(19) United States
(12) Patent Application Publication
(10) Pub. No.: US 2012/0104388 A1
(43) Pub. Date: May 3, 2012

(54) THREE-DIMENSIONAL STACKED SEMICONDUCTOR INTEGRATED CIRCUIT AND TSV REPAIR METHOD THEREOF

(75) Inventors: Min Seok CHOI, Ichon-shi (KR); Sang Jin BYEON, Ichon-shi (KR); Young Jun KU, Ichon-shi (KR)

(73) Assignee: Hynix Semiconductor Inc., Ichon-shi (KR)

(21) Appl. No.: 12/970,923

(22) Filed: Dec. 16, 2010

(30) Foreign Application Priority Data
Oct. 29, 2010 (KR) 10-2010-0106863

(51) Int. Cl. H01L 23/58; H01L 21/30

(52) U.S. Cl. 257/48; 438/4; 257/E23.002; 257/E21.211

(57) ABSTRACT

Provided is a 3D stacked semiconductor integrated circuit including a plurality of chips coupled through a plurality of TSVs. A first chip among the plurality of chips is configured to detect and repair a defective TSV among the plurality of TSVs, and transmit repair information to remaining chips other than the first chip, and the remaining chips other than the first chip are configured to repair the defective TSV in response to the repair information.

### CROSS-REFERENCES TO RELATED APPLICATION

The present application claims priority under 35 U.S.C. §119(a) to Korean Application No. 10-2010-0106863, filed on Oct. 29, 2010, in the Korean Intellectual Property Office, which is incorporated herein by reference in its entirety as if set forth in full.

### BACKGROUND

1. Technical Field

The present invention relates to a semiconductor circuit, and more particularly, to a three-dimensional (3D) stacked semiconductor integrated circuit and a through silicon via (TSV) repair method thereof.

2. Related Art

In order to increase the degree of integration of a semiconductor circuit, a 3D stacked semiconductor integrated circuit has been developed. The 3D stacked semiconductor integrated circuit includes a plurality of chips stacked and packaged within a single package to increase the degree of integration.

Recently, there has been used a method in which a plurality of stacked chips are electrically coupled by using TSVs.

Referring to FIG. 1, a 3D stacked semiconductor integrated circuit 1 has a structure in which a plurality of chips CHIP0 to CHIP3 are stacked on a substrate 2 and coupled through a plurality of TSVs.

The plurality of chips CHIP0 to CHIP3 are configured to commonly receive a variety of signals such as data, addresses, and commands through the plurality of TSVs. However, various defects may occur in the TSVs. For example, the defects may include a void which occurs when a TSV is not completely filled with a conductive material, a bump contact fail which occurs when a chip is bent or a bump material is moved, and a crack which occurs in a TSV.

As described above, the TSVs serve to electrically couple the plurality of chips. Therefore, when a TSV is opened in the middle due to a defect, the TSV is incapable of normal functions. Accordingly, a test should be performed to detect whether TSVs have a defect or not. According to the conventional technology, a test is performed by the following process: external equipment is used to monitor the respective TSVs and the test related data are stored. Thereafter, a separate program is used to repair a TSV in which a defect occurred.

In such a method, however, a considerably large amount of time is required for the test and repair process, and the number of packages to be tested at the same time is limited due to the limitations of a channel which may be used by the external equipment and a memory for storing the test related data.

### SUMMARY

Accordingly, there is a need for a 3D stacked semiconductor integrated circuit and a TSV repair method thereof, which are capable of reducing a test time and performing a repair operation. It should be understood, however, that some aspects of the invention may not necessarily obviate the problem.

In the following description, certain aspects and embodiments will become evident. It should be understood that these aspects and embodiments are merely exemplary, and the invention, in its broadest sense, could be practiced without having one or more features of these aspects and embodiments.

In one embodiment of the present invention, there is provided a three-dimensional (3D) stacked semiconductor integrated circuit including a plurality of chips coupled through a plurality of TSVs. A first chip among the plurality of chips is configured to detect and repair a defective TSV among the plurality of TSVs, and transmit repair information to remaining chips other than the first chip, and the remaining chips other than the first chip are configured to repair the defective TSV in response to the repair information.

In another embodiment of the present invention, a TSV repair method of a 3D stacked semiconductor integrated circuit, in which a plurality of chips are coupled through a plurality of TSVs, includes the steps of: detecting, by a first chip among the plurality of chips, a defective TSV among the plurality of TSVs; transmitting, by the first chip, repair information to remaining chips other than the first chip, after repairing the defective TSV; and repairing, by the remaining chips other than the first chip, the defective TSV in response to the repair information.

### BRIEF DESCRIPTION OF THE DRAWINGS

The accompanying drawings, which are incorporated in and constitute a part of this specification, explain various embodiments consistent with the invention and, together with the description, serve to explain the principles of the invention.

FIG. 1 is a cross-sectional view of a conventional 3D stacked semiconductor integrated circuit;

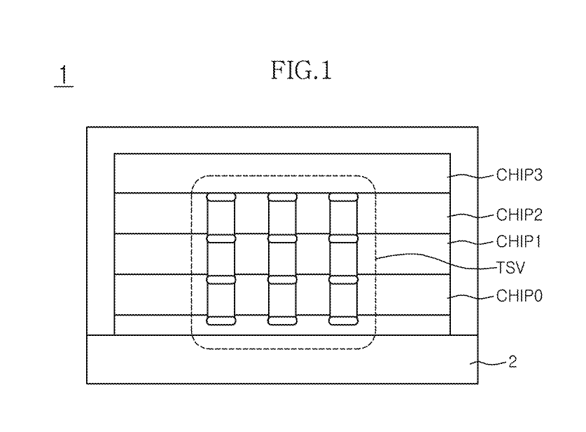

FIG. 2 is a block diagram of a 3D stacked semiconductor integrated circuit according to one embodiment of the invention;

FIG. 3 is a block diagram illustrating the configuration of a test block of FIG. 2;

FIG. 4 is a circuit diagram of a comparison unit of FIG. 3;

FIG. 5 is a block diagram illustrating the configuration of a detection unit of FIG. 3;

FIG. 6 is a circuit diagram of a unit detection section of FIG. 5;

FIG. 7 is a test operation timing diagram according to the embodiment;

FIG. 8 is a circuit diagram of a repair signal generation unit of FIG. 3; and

FIG. 9 is a circuit diagram of a transmitter/receiver (RX/TX) of FIG. 2.

### DETAILED DESCRIPTION

Reference will now be made in detail to the exemplary embodiments consistent with the present disclosure, examples of which are illustrated in the accompanying drawings. Wherever possible, the same reference characters will be used throughout the drawings to refer to the same or like parts.

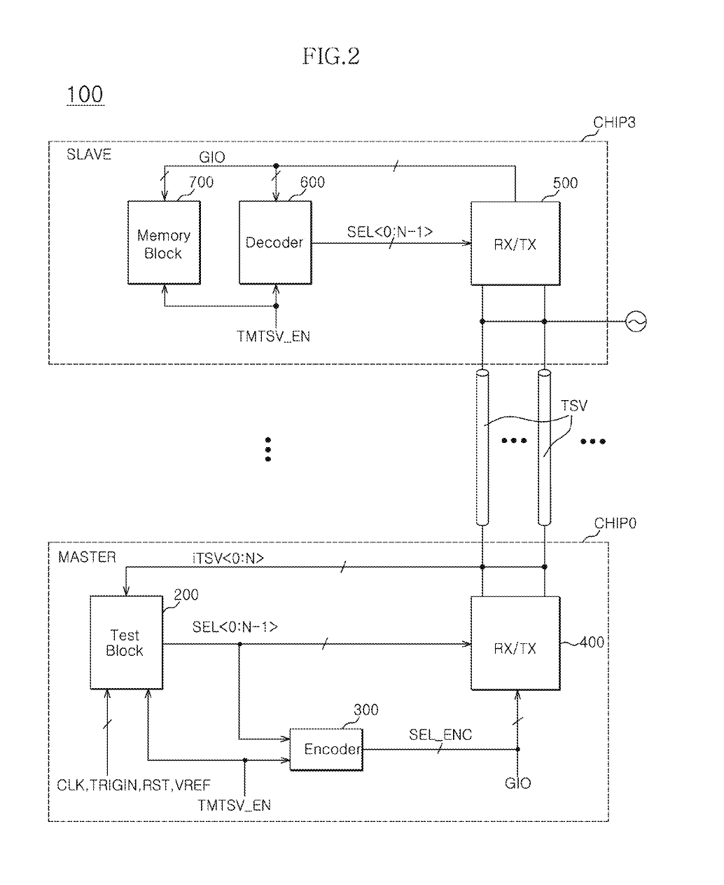

FIG. 2 is a block diagram of a 3D stacked semiconductor integrated circuit according to one embodiment. Referring to FIG. 2, a 3D stacked semiconductor integrated circuit 100 according to one embodiment includes a plurality of chips CHIP0 to CHIP3 stacked therein, and the plurality of chips CHIP0 to CHIP3 are coupled through a plurality of TSVs.

The plurality of chips CHIP0 to CHIP3 are configured to commonly receive a variety of signals such as data, addresses, and commands through the plurality of TSVs.

At this time, the plurality of chips CHIP0 to CHIP3 may be classified into a master and slaves.

In this embodiment, the chip CHIP0 is implemented as the master and the other chips are implemented as the slaves. Hereinafter, the chip CHIP0 is referred to as a master, and the chip CHIP3 is referred to as a slave.

All the slaves CHIP1 to CHIP3 are configured in the same manner.

The plurality of TSVs may include a normal TSV which is used to transmit a variety of signals such as data, addresses, and commands and a redundant TSV which is used to replace a defective TSV.

The master is configured to detect a defective TSV, i.e., a TSV having a defect, by using an amount of current flowing in each of the TSVs, in response to a test signal TMTSV_EN and replace the defective TSV with a normal TSV in response to repair information generated based on the detection result. Furthermore, the master is configured to transmit the repair information to the slaves through an intact TSV, i.e., a TSV having no defect, among the plurality of TSVs.

In this case, the master transmits the repair information to the slaves through the normal TSV next to the defective TSV among the plurality of TSVs.

At this time, the master uses a repair signal SEL<0:N-1> including a plurality of bits as the repair information, and transmits an encoded signal SEL_ENC obtained by encoding the repair signal SEL<0:N-1> to the slaves through the normal TSV next to the defective TSV.

The master includes a test block 200, an encoder 300, and a transmitter/receiver (RX/TX) 400.

The test block 200 is configured to receive a clock signal CLK, a pulse signal TRIGIN, a reset signal RST, a reference voltage VREF, and currents iTSV<0:N>flowing through the respective TSVs, detects a defective TSV, and generates a repair signal SEL<0:N-1> based on the detection result.

Here, the pulse signal TRIGIN is a signal for starting a test operation and is generated to have a pulse width of 1tCK. The pulse signal TRIGIN may be received from outside and generated through an internal pulse generator (not illustrated).

The encoder 300 is configured to generate the encoded signal SEL_ENC by encoding the repair signal SEL<0:N-1>.

The test block 200 and the encoder 300 are configured to operate during an activation period of the test signal TMTSV_EN.

The transmitter/receiver 400 is configured to transmit the encoded signal SEL_ENC to the TSVs through global lines GIO, after the defective TSV is replaced with a normal TSV based on the repair signal SEL<0:N-1>.

Here, the encoded signal SEL_ENC is a signal generated while the repair signal SEL<0:N-1> passes through the encoder 330. Therefore, after the TSV replacement of the transmitter/receiver 400 is performed by the repair signal SEL<0:N-1>, the encoded signal SEL_ENC is inputted to the transmitter/receiver 400.

The slave is configured to supply a current to the plurality of TSVs, and replace the defective TSV with a normal TSV in response to the repair information, that is, the encoded signal SEL_ENC.

The slave is configured to replace the defective TSV with a normal TSV in response to the repair signal SEL<0:N-1> restored by decoding the encoded signal SEL_ENC.

The slave includes a pad (not illustrated) configured to couple an external current source.

The slave includes a transmitter/receiver 500, a decoder 600, and a memory block 700. The transmitter/receiver 500 may be configured in the same manner as the transmitter/receiver 400 of the master. The transmitter/receiver 500 is configured to receive the encoded signal SEL_ENC and transmit the received signal to the global lines GIO.

The transmitter/receiver 500 is configured to replace the defective TSV with a normal TSV in response to the repair signal SEL<0:N-1>, after transmitting the encoded signal SEL_ENC to the global lines GIO.

The decoder 600 is configured to restore repair signal SEL<0:N-1> by decoding the encoded signal SEL_ENC inputted through the global lines GIO during the activation period of the test signal TMTSV_EN, and provide the repair signal SEL<0:N-1> to the transmitter/receiver 500.

The memory block 700 is configured to block data from being written during the activation period of the test signal TMTSV_EN.

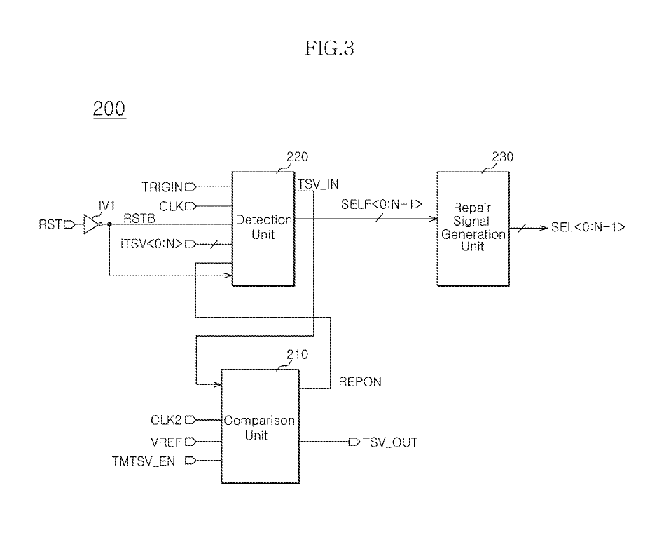

FIG. 3 is a block diagram illustrating the configuration of a test block of FIG. 2. Referring to FIG. 3, the test block 200 includes a comparison unit 210, a detection unit 220, and a repair signal generation unit 230. Furthermore, the test block 200 includes an inverter IV1 configured to generate an inverted reset signal RSTB.

The comparison unit 210 is configured to compare a current signal TSV_IN with a reference voltage VREF in response to the test signal TMTSV_EN and generate a comparison signal REPON. When the test signal TMTSV_EN is deactivated, the comparison unit 210 outputs the current signal TSV_IN as an output signal TSV_OUT to the outside through a pad.

In this embodiment, as the current signal TSV_IN is outputted as the output signal TVS_OUT to the outside through the pad, the TSV test may be performed in an outside circuitry, if necessary.

The detection unit 220 is configured to sequentially receive the currents iTSV<0:N> flowing through the plurality of TSVs based on the pulse signal TRIGIN, provide the received currents as the current signal TSV_IN to the comparison unit 210, and generate a detection signal SELF<0:N-1> for defining the defective TSV in response to the comparison signal REPON and the rest signal RST.

The repair signal generation unit 230 is configured to generate the repair signal SEL<0:N-1> in response to the detection signal SELF<0:N-1>.

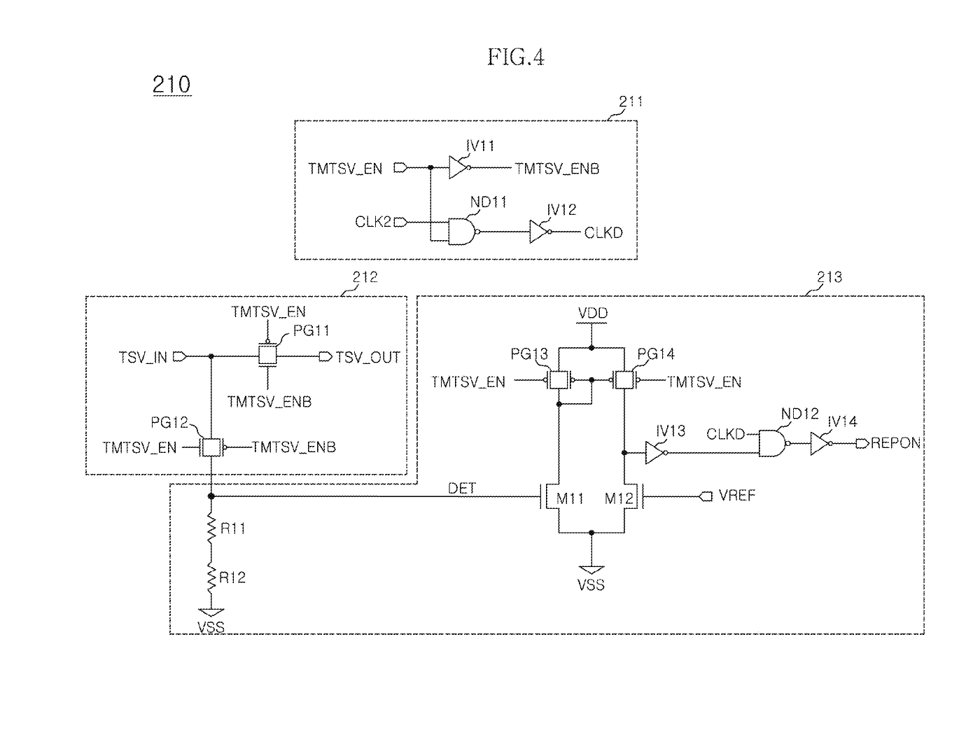

FIG. 4 is a circuit diagram of a comparison unit of FIG. 3. Referring to FIG. 4, the comparison unit 210 includes a timing control logic 211, a switching logic 212, and a comparator 213. The timing control logic 211 includes a plurality of inverters IV11 and IV12 and a NADN gate ND11.

The comparison unit 210 is configured to receive the test signal TMTSV_EN and a second clock signal CLK2 and generate an inverted test signal TMTSV_ENB and a third clock signal CLKD.

At this time, the second clock signal CLK2 is a signal obtained by shifting the clock signal CLK by ¾ phase.

The third clock signal CLKD is a signal obtained by performing an AND operation on the second clock signal CLK2 and the test signal TMTST_EN.

The switching logic 212 includes a plurality of pass gates PG11 and PG12.

The switching logic 212 is configured to input the current signal TSV_IN to the comparator 213 when the test signal TMTSV_EN is activated, and output the current signal TSV_IN as the output signal TSV_OUT to the outside through a pad when the test signal TMTSV_EN is deactivated.

The comparator 213 includes a plurality of resistors R11 and R12, a plurality of pass gates PG13 and PG14, a plurality of transistors M11 and M12, a plurality of inverters IV13 and IV14, and a NAND gate ND12.

The comparator 213 is configured to compare a voltage DET obtained by converting the current signal TSV_IN through the resistors with a reference voltage VREF and generate a comparison signal REPON during the activation period of the test signal TMTSV_EN. At this time, the comparator 213 synchronizes the comparison signal REPON with the third clock signal CLKD, and outputs the synchronized signal.

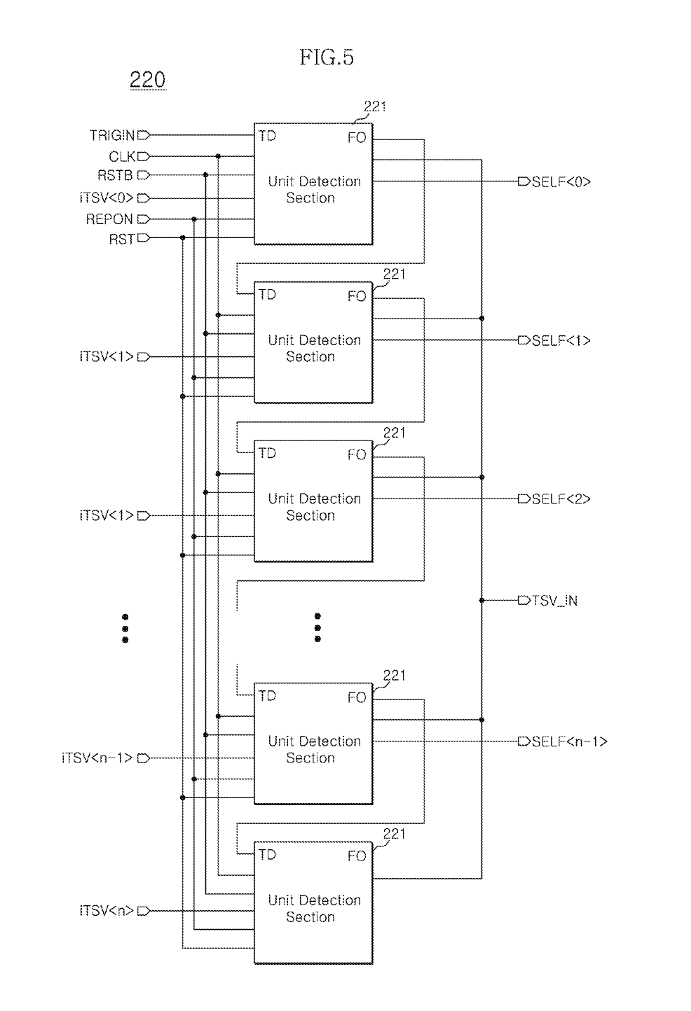

FIG. 5 is a block diagram illustrating the configuration of a detection unit of FIG. 3. Referring to FIG. 5, the detection unit 220 includes a plurality of unit detection sections 221.

The plurality of unit detection sections 221 may be configured in the same manner.

The plurality of unit detection sections 221 are configured to commonly receive the clock signal CLK, the reset signal RST, the inverted reset signal RSTB, and the comparison signal REPON, and receive the currents iTSV<0:N>flowing through the respective TSVs.

Among the plurality of unit detection sections 221, a first unit detection section, that is, a unit detection section receiving the current iTSV<0> flowing through a zero-th TSV receives the pulse signal TRIGIN through a terminal TD. Then, the first unit detection section provides a detection period signal F0 generated by using the pulse signal TRIGIN to a terminal TD of the next unit detection section.

The plurality of unit detection sections 221 have current signal (TSV_IN) output terminals which are commonly coupled.

At this time, since the current signals TSV_IN are outputted from the respective unit detection sections 221 with a predetermined timing difference provided therebetween, the current signal output terminals may be commonly coupled.

The plurality of unit detection sections 221 are configured to activate the detection signal SELF<0:N-1> when the comparison signal REPON is activated during the high-level period of the detection period signal F0.

The plurality of unit detection sections 221 are configured to reset, that is, deactivate the detection signal SELF<0:N-1> in response to the activation of the reset signal RST.

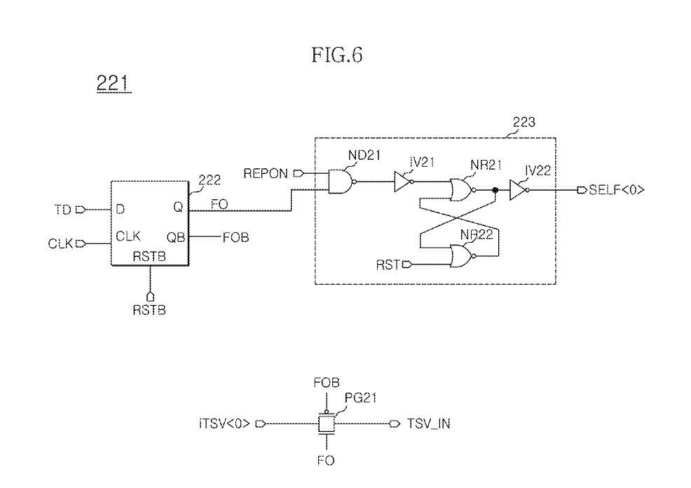

FIG. 6 is a circuit diagram of a unit detection section of FIG. 5. Referring to FIG. 6, the unit detection section 221 receiving the current iTSV<0> includes a D flip-flop 222, a latch 223, and a pass gate PG21.

The D flip-flop 222 is configured to latch the pulse signal TRIGIN inputted through the terminal TD at a rising edge of the clock signal CLK and output the latched pulse signal TRIGIN as the detection period signal F0 at a falling edge of the clock signal CLK.

The latch 223 includes a NAND gate ND21, a plurality of NOR gate NR21 and NR22, and a plurality of inverters IV21 and IV22.

The latch 223 is configured to output the detection signal SELF<0> as a high level when the comparison signal REPON is at a high level during the high-level period of the detection period signal F0, and change the detection signal SELF<0> to a low level when the reset signal RST is inputted as a high level.

The pass gate PG21 is configured to provide the current iTSV<0> as the current signal TSV_IN to the comparison unit 210 during the high-level period of the detection period signal F0.

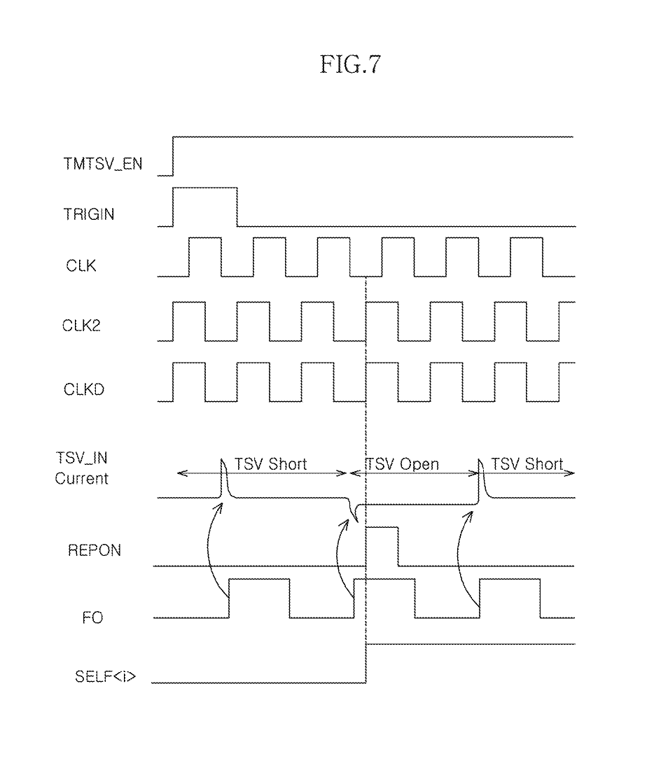

The operations of the comparison unit 210 and the detection unit 210 configured in such a manner will be described with reference to FIG. 7.

When entering a test mode, the test signal TMTSV_EN is activated, and the current source is coupled through the pad of the uppermost slave CHIP3 of FIG. 2.

Then, the unit detection unit 221 of FIG. 6 generates the detection period signal F0 in response to the pulse signal TRIGIN.

At each activation period of the detection period signal F0, the currents iTSV<0:N> flowing through the respective TSVs are sequentially provided to the comparison unit 220.

Since the test signal TMTSV_EN is activated, the current signal TSV_IN is provided to the comparator 213.

The comparator 213 compares the voltages DET obtained by converting the current signal TSV_IN with the reference voltage VREF and generates the comparison signal REPON.

That is, the comparator 213 sequentially compares the voltages DET obtained by converting the current signal TSV_IN generated according to the currents iTSV<0:N> flowing through the respective TSVs with the reference voltage VREF and generates the comparison signal REPON.

FIG. 7 is a test operation timing diagram according to the embodiment. Here, referring to FIG. 7, when a TSV corresponding to the current signal TSV_IN is shorted, the current amount of the current signal TSV_IN will increase in response to the activation of the detection period signal F0. When the TSV is opened, the current amount of the current signal TSV_IN will decrease in response to the activation of the detection period signal F0.

That is, when the TSV is shorted, the voltage DET obtained by converting the current signal TSV_IN is higher than the reference voltage VREF, and when the TSV is opened, the voltage DET is lower than the reference voltage VREF.

Therefore, the comparison signal REPON corresponding to the shorted TSV becomes a low level, and the comparison signal REPON corresponding to the opened TSV becomes a high level.

Accordingly, in the detection signal SELF<0:N-1>, a detection signal SELF<i> generated by testing the opened TSV is activated to a high level.

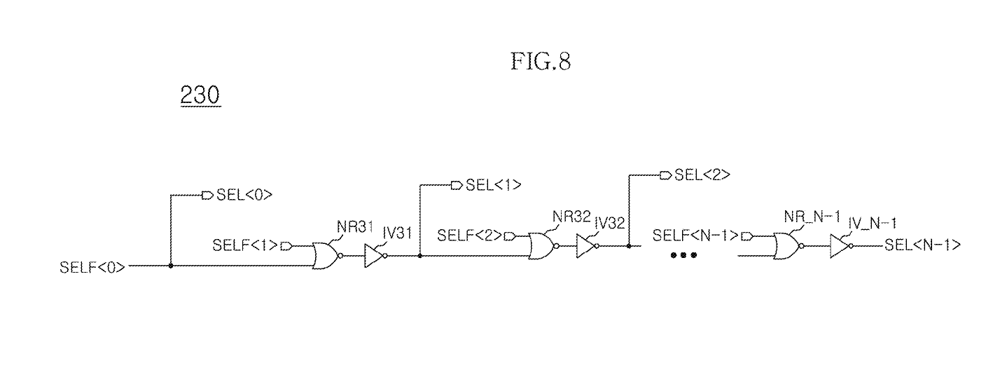

FIG. 8 is a circuit diagram of a repair signal generation unit of FIG. 3. Referring to FIG. 8, the repair signal generation unit 230 includes a plurality of NOR gates NR31 to NR_N-1 and a plurality of inverters IV31 to IVN-1.

The repair signal generation unit 230 is configured to output the repair signal SEL<0:N-1> corresponding to bits following an activated signal bit in the detection signal SELF<0:N-1>, as a high level.

For example, the repair signal generation unit 230 outputs the repair signal SEL<1:N-1> as a high level, when the detection signal SELF<1> is activated.

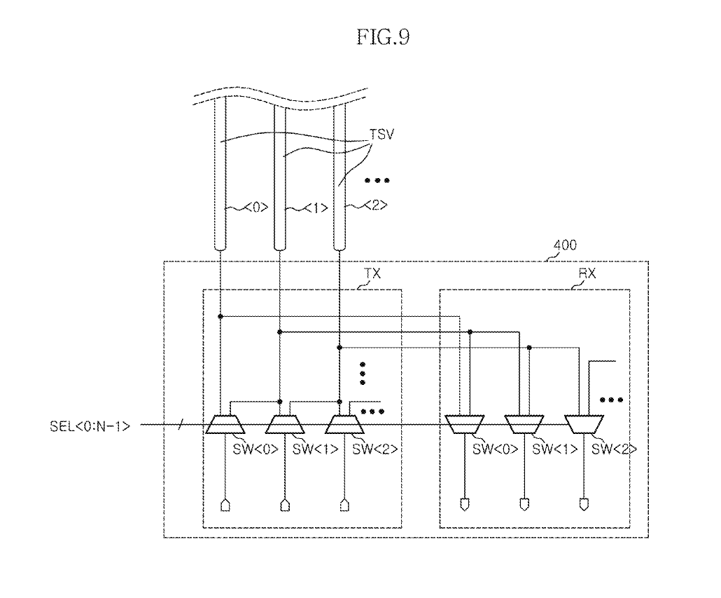

FIG. 9 is a circuit diagram of a transmitter/receiver (RX/TX) of FIG. 2. Referring to FIG. 9, the transmitter/receiver 400 includes a transmitter TX and a receiver RX.

Each of the transmitter TX and the receiver RX includes a plurality of switches SW<0:N-1>. At this time, the plurality of switches SW<0:N-1> may be implemented as multiplexers MUX.

The transmitter TX is configured to transmit an input signal, for example, data through any one of two adjacent TSVs in response to the repair signal SEL<0:N-1>.

For example, the switch SW<0> of the transmitter TX transmits data through any one of two TSVs coupled to the global lines GIO<0:1> according to the repair signal SEL<0>.

The receiver RX is configured to receive any one of signals transmitted through two adjacent TSVs in response to the repair signals SEL<0:N-1>.

For example, the switch SW<0> of the receiver RX receives data transmitted through any one of two TSVs coupled to the global lines GIO<0:1> according to the repair signal SEL<0>.

Hereinafter, the test operation according to the embodiment will be described.

For example, it is assumed that the zero-th TSV is opened.

The test block 200 of FIG. 2 detects the opened state of the zero-th TSV and outputs the repair signal SEL<0:N-1> based on the detection result. For example, when N is 3, the test block 200 outputs the repair signal SEL<0:2> as ‘111’.

At this time, referring to FIG. 6, the level of the voltage DET obtained by converting the current signal TSV_IN based on the current iTSV<0> according to the zero-th TSV is lower than that of the reference voltage VREF. Therefore, the first signal bit SELF<0> of the detection signal SELF<0:2> is outputted as a high level, and the other signal bits SELF<1:2> are outputted as a low level.

Referring to FIG. 8, since the detection signal SELF<0> is at a high level, the repair signal SELF<0:2> is outputted as ‘111’.

The transmitter/receiver 400 replaces the defective TSV with a normal TSV according to the repair signal SELF<0:2>.

Referring to FIG. 9, the coupling state between the plurality of switches SW<0:N-1> of the receiver RX of the transmitter/receiver 400 and the TSVs is switched according to the repair signal SEL<0:N-1>, that is, ‘111’.

That is, as the repair signal <0> is outputted ‘1’, the switch SW<0> outputs data through the first TSV instead of the zero-th TSV.

Similarly, as the entire repair signal <1:N-1> is outputted as ‘1’, the switches SW<1:N-1> output data through the second to N-th TSVs instead of the first to (N-1)-th TSVs.

At this time, the N-th TSV may serve as a redundant TSV.

The coupling state between the plurality of switches SW<0:N-1> of the receiver RX and the TSVs is also switched in the same manner as the transmitter TX.

Meanwhile, the encoder 300 encodes the repair signal SEL<0:N-1> and generates the encoded signal SEL_ENC.

At this time, the encoded signal SEL_ENC may be transmitted through the global lines GIO.

When any one of the TSVs corresponding to the global lines GIO has a defect, the encoded signal SEL_ENC may be encoded as a signal of which only one signal bit is at a high level, the signal bit being transmitted through the global line GIO<i>corresponding to the TSV next to the defective TSV.

For example, when a TSV corresponding to a third global line of 8 global lines has a defect, the encoded signal SEL_ENC may become a signal ‘00010000’ in which only a signal bit corresponding to a fourth global line is at a high level.

Furthermore, when a TSV other than the TSVs corresponding to the global lines GIO has a defect, the sequence of the defective TSV may be encoded as an 8-bit signal corresponding to 8 global lines.

As such, the transmitter/receiver 400 in which the TSV replacement has been completed by the repair signal SEL<0:N-1> transmits the encoded signal SEL_ENC through the global lines through the above-described method.

Subsequently, the encoded signal SEL_ENC received through the transmitter/receiver 500 of the slave is transmitted through the internal global lines GIO.

The decoder 600 generates the repair signal SEL<0:N-1> by decoding the encoded signal SEL_ENC, that is, decoding the encoded signal SEL_ENC.

While the decoder 600 operates during the activation period of the test signal TMTSV_EN, the data input of the memory block 700 is blocked during the activation of the test signal TMTSV_EN.

That is, although the encoded signal SEL_ENC is transmitted through the global lines GIO, the encoded signal SEL_ENC is not actual data. Therefore, the test signal TMTSV_EN is used to block the encoded signal SEL_ENC from being written into the memory block 700.

According to the repair signal SEL<0:N-1> outputted from the decoder 700, the transmitter/receiver 500 replaces the defective TSV with a normal TSV.

As described above, after the TSV repair operation is completed, the test signal TMTSV_EN is deactivated, and the test mode is switched to a normal operation mode. Furthermore, the coupling between the uppermost slave and the current source is canceled.

Accordingly, the operations of the encoder 300 and the decoder 600 are stopped, and the master and the slaves transmit/receive normal data, commands, or addresses through the repaired TSV.

While certain embodiments have been described above, it will be understood to those skilled in the art that the embodiments described are by way of example only. Accordingly, the 3D stacked semiconductor integrated circuit and the TSV repair method thereof described herein should not be limited based on the described embodiments. Rather, the 3D stacked semiconductor integrated circuit and the TSV repair method thereof described herein should only be limited in light of the claims that follow when taken in conjunction with the above description and accompanying drawings.

What is claimed is:

1. A three-dimensional (3D) stacked semiconductor integrated circuit comprising a plurality of chips coupled through a plurality of through silicon vias (TSVs),
wherein a first chip among the plurality of chips is configured to detect and repair a defective TSV among the plurality of TSVs, and transmit repair information to remaining chips other than the first chip, and
the remaining chips other than the first chip are configured to repair the defective TSV in response to the repair information.

2. The 3D stacked semiconductor integrated circuit according to claim 1, wherein the first chip is configured to transmit the repair information to the remaining chips through a TSV having no defect among the plurality of TSVs.

3. The 3D stacked semiconductor integrated circuit according to claim 1, wherein the first chip is configured to transmit the repair information to the remaining chips through the TSV next to the defective TSV.

4. The 3D stacked semiconductor integrated circuit according to claim 1, wherein the repair information is transmitted through TSVs used for data transmission.

5. The 3D stacked semiconductor integrated circuit according to claim 1, wherein the first chip comprises:
a test block configured to receive currents flowing through the respective TSVs, detect the defective TSV, and generate a repair signal based on a detection result;
an encoder configured to encode the repair signal and generate an encoded signal; and
a transmitter/receiver configured to replace the defective TSV with a normal TSV according to the repair signal, and then transmit the encoded signal to the remaining chips.

6. The 3D stacked semiconductor integrated circuit according to claim 5, wherein the test block and the encoder are configured to operate during an activation period of a test signal.

7. The 3D stacked semiconductor integrated circuit according to claim 6, wherein the test block comprises:
a comparison unit configured to compare a voltage obtained by converting a current signal with a reference voltage and generate a comparison signal, in response to the activation of the test signal;
a detection unit configured to sequentially receive the currents flowing through the respective TSVs according to a pulse signal, outputs the received currents as the current signal, and generate a detection signal for defining the defective TSV in response to the comparison signal; and
a repair signal generation unit configured to generate the repair signal in response to the detection signal.

8. The 3D stacked semiconductor integrated circuit according to claim 7, wherein the comparison unit is configured to output the current signal to the outside of the first chip, when the test signal is deactivated.

9. The 3D stacked semiconductor integrated circuit according to claim 7, wherein the detection unit is configured to activate the detection signal, when the comparison signal is activated during an activation period of a detection period signal.

10. The 3D stacked semiconductor integrated circuit according to claim 7, wherein the repair signal generation unit is configured to activate signal bits of the repair signal corresponding to bits following an activated signal bit among signal bits of the detection signal.

11. The 3D stacked semiconductor integrated circuit according to claim 5, wherein the transmitter/receiver comprises:
a transmitter configured to transmit an input signal through any one of two adjacent TSVs in response to the repair signal; and
a receiver configured to receive one of signals transmitted through two adjacent TSVs in response to the repair signal.

12. The 3D stacked semiconductor integrated circuit according to claim 1, wherein a second chip stacked at the uppermost position among the remaining chips is configured to supply currents to the plurality of TSVs.

13. The 3D stacked semiconductor integrated circuit according to claim 12, wherein the second chip includes a pad configured to couple an external current source.

14. The 3D stacked semiconductor integrated circuit according to claim 12, wherein the second chip comprises:
a transmitter/receiver configured to receive the repair information, transmit the received repair information to internal global lines, and replace the defective TSV with a normal TSV in response to a repair signal; and
a decoder configured to decode repair information transmitted through the internal global lines and generate the repair signal.

15. The 3D stacked semiconductor integrated circuit according to claim 14, wherein the transmitter/receiver comprises:
a transmitter configured to transmit an input signal through any one of two adjacent TSVs in response to the repair signal; and
a receiver configured to receive one of signals transmitted through two adjacent TSVs in response to the repair signal.

16. The 3D stacked semiconductor integrated circuit according to claim 14, wherein the decoder is configured to decode the repair information and generate the repair signal, during an activation signal of a test signal.

17. The 3D stacked semiconductor integrated circuit according to claim 14, further comprising a memory block configured to block data from being written, during an activation period of a test signal.

18. A TSV repair method of a 3D stacked semiconductor integrated circuit in which a plurality of chips are coupled through a plurality of TSVs, the TSV repair method comprising the steps of:
detecting, by a first chip among the plurality of chips, a defective TSV among the plurality of TSVs;
transmitting, by the first chip, repair information to remaining chips other than the first chip, after repairing the defective TSV; and
repairing, by the remaining chips other than the first chip, the defective TSV in response to the repair information.

19. The TSV repair method according to claim 18, further comprising the step of providing, by a second chip stacked at the uppermost position among the remaining chips, currents to the plurality of TSVs.

20. The TSV repair method according to claim 19, wherein, in the step of detecting the defective TSV, currents flowing through the respective TSVs are measured to detect the defective TSV.

21. The TSV repair method according to claim 18, wherein the step of transmitting the repair information comprises the step of transmitting the repair information to the remaining chips through a TSV having no defect among the plurality of TSVs.

22. The TSV repair method according to claim 18, wherein the step of transmitting the repair information comprises the step of transmitting the repair information to the remaining chips through the TSV next to the defective TSV.

23. The TSV repair method according to claim 18, wherein the step of transmitting the repair information comprises the step of transmitting the repair information to the remaining chips through TSVs used for data transmission among the plurality of TSVs.
